(19) United States
(12) Patent Application Publication
(10) Pub. No.: US 2002/0013044 A1
(43) Pub. Date: Jan. 31, 2002

(54) HDP liner layer prior to HSQ/SOG deposition to reduce the amount of HSQ/SOG over the metal lead

(76) Inventors: Rafael A. Mena, Allen, TX (US); Philip E. Hecker JR., Dallas, TX (US); Alfred J. Griffin JR., Dallas, TX (US)

Correspondence Address: TEXAS INSTRUMENTS INCORPORATED, P O BOX 655474, M/S 3999, DALLAS, TX, 75265

(21) Appl. No.: 09/895,524

(22) Filed: Jun. 28, 2001

Related U.S. Application Data
(60) Provisional application No. 60/221,050, filed on Jul. 27, 2000.

(51) Int. Cl. H01L 23/48; H01L 23/52; H01L 21/4763

(52) U.S. Cl. 438/622; 257/774; 257/751; 257/758; 257/762; 438/624

(57) ABSTRACT

A dielectric layer (112) having a HDP liner layer (104) under the dielectric gap-fill layer (106) (e.g., HSQ/SOG). The HDP process has a deposition and a sputter-etch component. The sputter-etch component results in an HDP liner (104) with a sloped edges on a portion (105) of the liner over the metal lead. The HDP liner (104) profile results in an effective decrease in the metal surface area which, in turn, limits the amount of dielectric fill (106) deposited over the lead.

### FIELD OF THE INVENTION

The invention is generally related to the field of interlevel dielectric layers for semiconductor devices and more specifically to forming an interlevel dielectric layer comprising HSQ (hydrogen silesquioxane) OR SOG (spin-on-glass).

### BACKGROUND OF THE INVENTION

For current integrated circuit (IC) technology, the speed limiting factor is no longer the transistor gate delay, but the RC delays associated with the interconnects. For this reason, a great deal of work has been done on developing new low dielectric constant materials to reduce interconnect capacitance. Some of these dielectrics include hydrogen silsesquioxane (HSQ), fluorinated silicon dioxide (FSG), polymers, aerogels, and xerogels. The development of new low dielectric constant materials has also necessitated significant work in integrating these materials into a semiconductor fabrication process flow.

A prior art method of integrating HSQ into an interlevel dielectric (ILD) is illustrated in FIGS. 1. After a metal interconnect line 12 is formed on a semiconductor body 10, a PETEOS (plasma enhanced tetraethyoxysilane) liner 14 is deposited over the metal interconnect liner 12, as shown in FIG. 1. A coat layer of HSQ 16 is then coated or spun-on the PETEOS liner 14. Finally, a PETEOS polish layer 18 is deposited over the HSQ coat layer 16. The stack is then chemically-mechanically polished (CMP). Typically, the HSQ is cured either after the coat step, after the PETEOS polish layer deposition, or after via etch.

Unfortunately, outgassing of the HSQ (or other SOG) may prevent the complete filling of the via during tungsten nucleation. The voiding in the via results in high resistance or open circuits and subsequent lower process and multi-probe yields. This problem is worsened as the HSQISOG thickness is increased in order to guarantee adequate gapfill between metal leads. Increasing the HSQ/SOG thickness results in a “pile-up” of HSQ/SOG on top of the metal lead. When making contact to the metal lead, the increased amount of HSQ/SOG on the metal lead results in more exposed HSQ and, therefore, more severe outgassing.

### SUMMARY OF THE INVENTION

The invention is a dielectric layer having a high density plasma (HDP) liner layer under the dielectric gap-fill layer (e.g., HSQ/SOG). The HDP process has a deposition and a sputter-etch component. The sputter-etch component results in an HDP liner with a sloped edges (e.g., triangular or trapezoidal in structure) over the metal lead. The HDP liner profile results in an effective decrease in the metal surface area which, in turn, limits the amount of dielectric fill coated over the lead.

An advantage of the invention is providing a method for forming a dielectric stack that minimizes voids in the vias.

This and other advantages will be apparent to those of ordinary skill in the art having reference to the specification in conjunction with the drawings.

### BRIEF DESCRIPTION OF THE DRAWINGS

In the drawings:

FIG. 1 is a cross-sectional diagram of a prior art interlevel dielectric using HSQ;

FIG. 2 is a cross-sectional diagram of an ILD layer using an HDP liner according to the invention; and

FIGS. 3A-3C are cross-sectional diagrams of a ILD layer of FIG. 2 at various stages of fabrication.

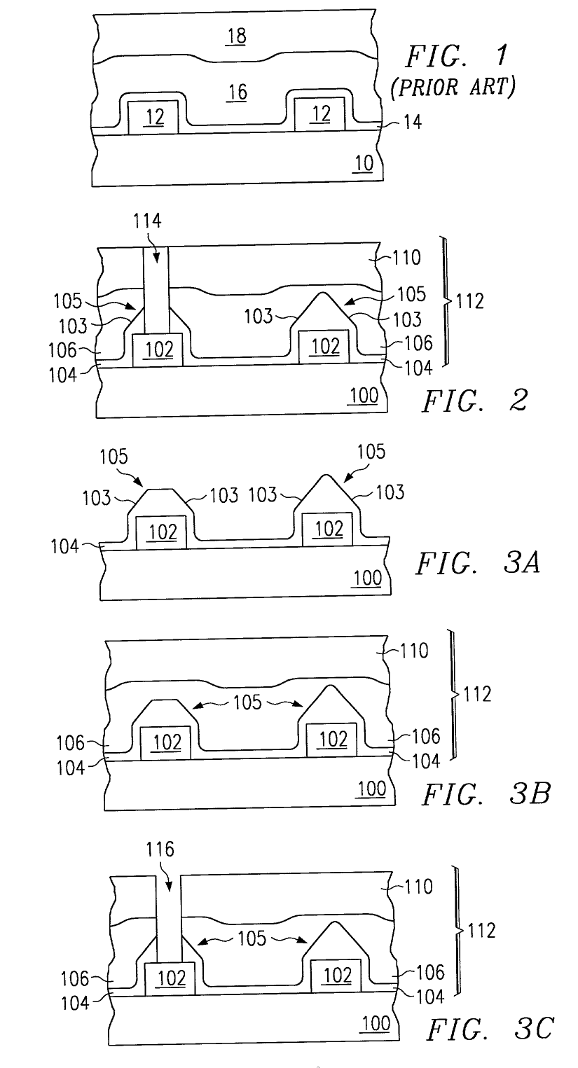

### DETAILED DESCRIPTION OF THE EMBODIMENTS

The invention will now be described in conjunction with forming an interlevel dielectric layer using HSQ. It will be apparent to those of ordinary skill in the art that the HDP liner layer of the invention may be applied to forming a liner for other dielectric materials, such as those in the class of spin-on-glass.

An interlevel dielectric layer (ILD) 112 according to the invention is shown in FIG. 2. The term interlevel dielectric layer is used generically herein to refer to intrametal dielectrics (dielectrics between metal leads) and intermetal dielectrics (dielectrics between metal interconnect layers—sometimes referred to as ILDs). In the following discussion, the intrametal dielectric and intermetal dielectric will be referred to collectively as ILD 112.

Metal leads 102 are located over semiconductor body 100. Semiconductor body 100 typically comprises a silicon substrate having transistors, isolation structures, etc. formed therein. Semiconductor body 100 may also contain one or more metal interconnect layers. Metal leads 102 will typically comprise an aluminum alloy with appropriate barrier layers (e.g., Ti, TiN). Other suitable materials for metal leads 102 are known in the art.

HDP liner layer 104 is located over and between metal leads 102. The portion 105 of HDP liner layer 104 on the surface of metal leads 102 has sloped edges 103. The shape of portion 105 is roughly triangular or trapezoidal depending on the thickness of the metal lead. HDP liner layer 104 preferably comprises HDP silicon dioxide. Fluorinated HDP oxide (HDP-FSG), or phosphorous doped HDP oxide (HDP-PSG) may alternatively be used. The thickness of HDP liner layer 104 is in the range of 500-8000 Å.

Gap-fill layer 106 is located over HDP liner layer 104 and fills the space between metal leads 102. Gap-fill layer 106 comprises HSQ in the preferred embodiment. However, other SOGs may alternatively be used.

A polish layer 110 is located over gap-fill layer 106. Polish layer 110 is sometimes called a capping layer or intermetal dielectric. As an example, polish layer 110 may comprises a PETEOS (plasma enhanced tetraethyoxysilane) layer. Other examples include silane-based oxides such as plasma enhanced fluorine doped silicate glass (PE-FSG). The thickness of intermetal dielectric layer 110 may be in the range of 1000-22,000 Å.

A conductive via 114 is embedded within intermetal dielectric layer 110 to provide connection to one of the metal leads 102. Conductive via 114 may, for example, comprise tungsten. Other suitable materials for conductive via 114 include copper or aluminum with appropriate barrier materials.

The portion 105 of HDP liner layer 104 on the surface of metal leads 102 results in less of the HSQ gap-fill layer being coated or deposited over the metal leads 102 (i.e., less pile up). Thus, conductive via 114 is in contact with less of the gap-fill material 106. HSQ is not a cross-linked material, so it may continue to outgas almost indefintely. Providing less of the gap-fill material 106 in contact with the via reduces the amount of outgassing from the gap-fill material into the via during the via barrier degas, barrier deposition, or the tungsten nucleation. Voids are thereby reduced and yield is improved.

A method of forming an interlevel dielectric 112 using an HDP (high density plasma) liner layer 104 under a HSQ gap-fill layer 106 is discussed with reference to FIGS. 3A-3C. An HDP process involves simultaneously depositing and sputtering a material such as silicon dioxide. HDP oxide deposition is defined as chemical vapor deposition with simultaneous dc-bias sputtering using a mixture of silicon containing (e.g., SiH₄), oxygen-containing (e.g., O₂), and nonreactive gases (e.g., a noble gas such as Ar). This method generally forms a high quality oxide with good thermal stability, low moisture uptake, and fine mechanical properties. The process variables such as gas flow rates, wafer temperature, source RF power and bias RF power are optimized such that there is a deposition of an SiO₂ film on the surface due to a reaction between the SiH₄ and O₂. The bias RF power is adjusted for a chosen value of source RF power to control the degree of sputtering. Typically, higher bias RF power results in more sputtering of the deposited film. The simultaneous deposition and dc-bias sputtering forms a capping portion over the metal leads that has sloped edges. In general, a higher etch to deposition ratio (E/D ratio) leads to greater sloped edges. As an example, the E/D ratio may be in the range of 0.18 to 0.40. HDP oxide deposition is described further in U.S. Pat. No. 5,494,854, issued Feb. 27, 1996 and hereby incorporated by reference.

Referring to FIG. 3A, a HDP liner layer 104 is deposited over metal leads 102 and semiconductor body 100. For example, semiconductor body 100 may comprise transistors formed in a silicon substrate and a PMD (pre-metal dielectric) layer isolating these transistors from the first layer of metal interconnect except where contacts are formed. Metal leads 102 may be part of the first or any subsequent metal interconnect layer except the upper most interconnect layer. Metal leads 102 may include barrier materials as is known n the art. Methods for forming semiconductor body 100 and metal leads 102 are well known in the art.

HDP liner layer 104 is deposited using an E/D ratio that creates sloped edges 103 on the portion 105 of HDP liner layer 104 on the surface of metal leads 102. The slope of edges 103 is on the order of 45°. While a steeper slope is better, the slope is not critical. The resulting shape of portion 105 is roughly triangular or trapezoidal depending on the thickness of the metal lead.

In the preferred embodiment, HDP liner 104 replaces the PETEOS liner of the prior art. However, if desired, a PETEOS liner or silane based oxide liner may be retained. In that case, the HDP liner 104 is formed over the other liner.

Referring to FIG. 3B, a gap-fill layer 106 is deposited over HDP liner layer 104. Gap-fill layer 106 is deposited to a thickness sufficient to fill the space between metal leads 102. Due to the portion 105 of HDP liner layer 104, only a minimal amount of gap-fill layer 106 is deposited over metal leads 102. Gap-fill layer may comprise HSQ or another SOG.

After gap-fill layer 106 is deposited, an intermetal dielectric layer 110 is deposited over gap-fill layer 106 and metal leads 102. Intermetal dielectric layer 110 may, for example, comprise PETEOS. The thickness of intermetal dielectric 110 may be in the range of 1000-22,000 Å. Intermetal dielectric layer 110 is preferably planarized.

Referring to FIG. 3C, a via 116 is etched in intermetal dielectric layer 110 to metal lead 102. Due to the fact that the amount of gap-fill material 106 present over the surface of metal leads 102 is reduced, only a small amount, if any, gap-fill material is exposed. Thus, outgassing is minimized.

Next, via 116 is filled with conductive material to form conductive via 114. As an example, a via barrier, such as PVD (physical vapor deposition) Ti/TiN or PVD Ti/CVD TiN, may be deposited followed by a tungsten nucleation, or other conductive metal fill. The resulting structure is shown in FIG. 2. Because outgassing is minimized, the number voids formed in vias 116 are minimized or eliminated.

Processing may then continue with the formation of additional interconnect layers, as desired, and packaging. The additional interconnect layers may include ILDs similar to ILD 112.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method of fabricating an integrated circuit comprising the steps of:
forming a HDP (high density plasma) liner layer over a semiconductor body having metal leads formed thereon, wherein a portion of said HDP liner layer over said metal leads has sloped edges;
forming a gap-fill layer over said liner layer, said gap-fill layer filling a space between closely-spaced ones of said metal leads;
forming a dielectric layer over said gap-fill layer and said metal leads; and
forming a via through said dielectric layer to at least one of said closely-spaced metal leads.

2. The method of claim 1, wherein said sloped edges have a slope on the order of 45°.

3. The method of claim 1, wherein said dielectric layer comprises PETEOS.

4. The method of claim 1, wherein said dielectric layer comprises a silane based oxide.

5. The method of claim 1, wherein the portion of HDP liner layer over the metal leads is approximately triangular shaped.

6. The method of claim 1, wherein the portion of HDP liner layer over the metal leads is approximately trapezoidal.

7. The method of claim 1, wherein said step of forming said HDP liner layer uses an etch-to-deposition ratio in the range of 0.18 to 0.40.

8. The method of claim 1, wherein said HDP liner layer comprises undoped HDP silicon dioxide.

9. The method of claim 1, wherein said HDP liner layer comprises fluorinated HDP oxide.

10. The method of claim 1, wherein said HDP liner layer comprises phosphorous doped HDP oxide.

11. The method of claim 1, wherein said gap-fill layer comprises a spin-on glass.

12. The method of claim 1, wherein said gap-fill layer comprises HSQ.

13. An integrated circuit, comprising:
a liner layer over a semiconductor body and a plurality of closely-spaced metal leads, wherein a portion of the liner layer over the metal leads has sloped edges; and
a gap-fill layer located over the liner layer and filling a space between said closely-spaced metal leads.

14. The integrated circuit of claim 13, wherein said gap-fill layer comprises HSQ.

15. The integrated circuit of claim 13, wherein said gap-fill layer comprises a spin-on glass.

16. The integrated circuit of claim 13, wherein the sloped edges have a slope on the order of 45°.

17. The integrated circuit of claim 13, wherein the portion of the liner layer over the metal leads is triangular shaped.

18. The integrated circuit of claim 13, wherein the portion of the liner layer over the metal leads is trapezoidal.
